(19) United States
(12) Patent Application Publication
(10) Pub. No.: US 2017/0208403 A1
(43) Pub. Date: Jul. 20, 2017

(54) PIEZOELECTRIC SENSORS FOR HEARING AIDS

(71) Applicant: Massachusetts Eye And Ear Infirmary, Boston, MA (US)

(72) Inventor: Hideko Heidi Nakajima, Andover, MA (US)

(73) Assignee: Massachusettes Eye And Ear Infirmary, Boston, MA (US)

(21) Appl. No.: 15/039,090

(22) PCT Filed: Nov. 25, 2014
(86) PCT No.: PCT/US2014/067450

§ 371 Date: May 25, 2016

Related U.S. Application Data
(60) Provisional application No. 61/908,237, filed on Nov. 25, 2013.
(60) Provisional application No. 62/045,955, filed on Sep. 4, 2014.

(51) Int. Cl. H04R 25/00; H01L 41/187; H01L 41/193; H01L 41/113

(52) U.S. Cl. CPC H04R 25/606; H01L 41/1132; H01L 41/1876; H01L 41/193

(57) ABSTRACT

This disclosure describes techniques and systems to aid hearing of subjects using implantable systems, e.g., fully implantable systems, which include a piezoelectric sensor to generate electric signals from detected acoustic vibrations of middle ear ossicles. The systems can include, for example, middle ear implants and cochlear implants.

### CROSS REFERENCE TO RELATED APPLICATIONS

This application claims priority from U.S. Provisional Application No. 61/908,237 filed on Nov. 25, 2013 and from U.S. Provisional Application No. 62/045,955 filed on Sep. 4, 2014, the entire contents of both of which are incorporated herein by reference.

### TECHNICAL FIELD

This invention relates to hearing aids.

### BACKGROUND

Humans and other animals can suffer from conductive hearing loss, where there is damage to the ossicular chain (bones of the middle ear). Treatment options include medical or surgical treatment, or various types of hearing aids such as middle ear implants and prosthetics. Another form of hearing loss is sensorineural hearing loss, where there is damage to hair cells in the cochlea (inner ear). In this case, damage to the hair cells in the cochlea degrades the transduction of acoustic information to electrical impulses in the auditory nerve. Treatment options include hearing aids such as cochlear implants that are devices used to stimulate the auditory nerves.

Conventional hearing aids typically include a microphone to pick up sound. The microphone is fixed external to the ear, which can raise social stigma and limit the usage of the microphone in the shower or during water sports.

### SUMMARY OF THE INVENTION

This disclosure describes techniques and systems to aid hearing of subjects (e.g., human or animal subjects) using implantable systems that include a piezoelectric sensor to detect acoustic vibrations. The piezoelectric sensor can generate electric signals from the detected acoustic vibrations. The systems can include middle ear implants, where the piezoelectric sensor generates and provides electric signals to a processing circuit that amplifies and sends the signals to a transducer to mechanically stimulate the oval window or round window of the ear. The systems can include cochlear or middle ear implants, where the piezoelectric sensor provides the generated electric signals to a processing circuit that applies electric stimulation pulses to auditory nerves. In certain implementations, the processing circuit can include circuits such as a sensor front-end circuit used to amplify the electric signals generated by the piezoelectric sensor. The systems can be fully implantable inside the ear.

In one general aspect, the disclosure covers implantable systems for providing auditory signals to a subject. The systems include a piezoelectric sensor configured to be implanted in the subject's middle ear to detect mechanical vibrations of the subject's umbo and to generate electric signals corresponding to the detected vibrations; and a support structure having an elongated shape, wherein a first end of the elongated support structure is configured to be connected to the piezoelectric sensor, and a second end of the support structure positioned away from the first end is configured to be fixed to a mastoid bone or other bony structure in the subject's middle ear.

In these systems, the piezoelectric sensor can have an elongated shape; and the support structure can include a ball joint that can be used to adjust an angle between the piezoelectric sensor and the support structure. In some implementations, the piezoelectric sensor is shaped as a slab and comprises a cup-like structure to contact the umbo. Alternatively, the piezoelectric sensor can include a portion shaped to encompass and contact the umbo of the subject.

In some implementations, the systems further include an anchor structure that is configured to be connected to one end of elongated shape of the piezoelectric sensor, wherein the one end of the piezoelectric sensor is opposite to another end of the piezoelectric sensor that connects to the support structure; wherein the anchor structure is configured to be fixed to a bony wall of the middle ear of the subject. In these systems, the anchor structure and/or the support structure can be made of or include material selected from the group consisting of titanium, plastic, silicone, and composite materials.

In some implementations, the piezoelectric sensor is shaped as a plate; the support structure includes an extension with a first surface and a second surface opposite to the first surface; the first surface faces towards the plate of the piezoelectric sensor and contacts the plate of the piezoelectric sensor; and the second surface faces away from the plate of the piezoelectric sensor and towards the cochlear promontory bone in the middle ear of the subject. For example, the extension can be shaped as a disc.

In other implementations, the systems further include a base element that is configured to contact a bottom surface of an extension; wherein the piezoelectric sensor, the extension, and the base element are arranged along a direction of motion of an umbo of the subject. For example, the base element can be made or include a compliant medical-grade silicone. In some implementations the base element is configured to be attached to the promontory of the cochlear bone in the middle ear with bone cement or other adhesive.

In another aspect, the disclosure covers methods for providing auditory signals to a subject. The methods include obtaining a piezoelectric sensor configured to be implanted in the subject's middle ear to detect mechanical vibrations of the subject's umbo and to generate electric signals corresponding to the detected vibrations; obtaining a support structure having an elongated shape, wherein a first end of the elongated support structure is configured to be connected to the piezoelectric sensor, and wherein a second end of the support structure positioned away from the first end is configured to be fixed to a mastoid bone or other bony structure in the subject's middle ear; connecting the first end of the support structure to the piezoelectric sensor; attaching the second end of the support structure to a mastoid bone or other bony structure in the subject's middle ear; connecting the piezoelectric sensor either directly or indirectly to the subject's umbo; detecting mechanical vibrations of the subject's umbo; and providing an auditory signal to the subject based on the detected mechanical vibrations.

In various implementations of these methods, adhesive is used to attach the support structure to the mastoid bone, and/or one or more screws are used to attach the support structure to the mastoid bone. In some implementations, of these methods the first end of the piezoelectric sensor comprises a ball joint; and the methods include adjusting an angle between the piezoelectric sensor and the support structure using the ball joint.

In some implementations the methods further include connecting an anchor structure to the first end of the piezoelectric sensor; and attaching the anchor structure to a bony structure in the middle ear of the subject. In these methods, the anchor structure can be made of or include a material selected from the group consisting of titanium, plastic, composite material, and silicone. In some implementations, the first end of the piezoelectric sensor comprises a portion shaped to encompass and contact the umbo and the support structure is made of or includes a material selected from the group consisting of titanium, plastic, composite material, and silicone.

In certain implementations of the methods, the piezoelectric sensor is shaped as a plate; the support structure comprises an extension with a first surface and a second surface opposite to the first surface; the first surface faces towards the plate of the piezoelectric sensor and is configured to contact the plate of the piezoelectric sensor; and the second surface faces away from the plate of the piezoelectric sensor and towards a bony cochlear promontory surface in the middle ear of the subject. For example, the extension can be shaped as a disc.

In some implementations, the methods further include positioning a base element to contact the bottom of the extension; wherein the piezoelectric sensor, the extension, and the base element are arranged along a direction of motion of the umbo of the subject. In some implementations, the base element is made of or includes a compliant medical-grade silicone. These methods can further include fixing the base element to the promontory of the cochlear bone in the middle ear using bone cement or other adhesive.

The techniques and systems disclosed herein enable a piezoelectric sensor to be mounted in the middle ear to extremely efficiently detect incoming sound pressure in the ear canal by detecting movement of middle ear structures such as the tympanic membrane or any region of one of the ossicles, e.g., the malleus, incus, or stapes (e.g., at the manubrium of the malleus). For example, the piezoelectric sensor can be located in the middle ear cavity and contact the umbo directly or one of the ossicles. The umbo is the location where the small tip of the manubrium of the malleus is firmly attached and enveloped by the medial and lateral layers of the tympanic membrane specifically at the center of the cone-shaped tympanic membrane. In another example, the piezoelectric sensor is located in the middle ear cavity and is coupled to a support structure (e.g., flexible beam) that directly contacts the umbo.

Generally, one or more support structures and anchor structures can be coupled to the piezoelectric sensor to anchor the piezoelectric sensor in a stable manner. The disclosed arrangements can provide mechanical impedance matching between the structure and the piezoelectric sensor/support structure arrangement to provide efficient detection of movement, e.g., umbo movement, without reducing the ossicular motion below an amount providing good ability to detect sound. In some implementations, the sound detected by the piezoelectric sensor can be processed by a processor circuit in a power-efficient manner in either a middle ear implant or a cochlear implant.

The techniques and systems disclosed in this specification provide numerous benefits and advantages (some of which can be achieved only in some of the various aspects and implementations) including the following. Given the new systems, the hearing aid devices can be implemented to sense incoming sound pressure by detecting movement of one of the structures in the middle ear, such as the umbo (where the end tip of the manubrium of the malleus is firmly attached and enveloped by the tympanic membrane), or any one of the ossicles, using a piezoelectric sensor. Because the umbo generally has the greatest displacement motion of any part of the middle-ear ossicular chain, and has generally predictable near one-dimensional motion for a wide frequency range, the umbo has advantages over other regions of the ossicular chain to couple a sensor. For example, other parts of the middle-ear ossicles have complicated modes of motion that changes with frequency, making it less stable for interfacing with a sensor. When stimulated by incoming sound pressure, the piezoelectric sensor can effectively and efficiently generate electric signals by measuring motion of the umbo. Thus, the piezoelectric sensor can generate a relatively large electric signal compared to the case where the sensor detects motion of other parts of the middle ear. Because of the relatively large electric signal, a processing circuit connected to the piezoelectric sensor can amplify the received electric signal with good signal-to-noise ratio (SNR).

In general, the disclosed systems use one or more support structures that anchor the piezoelectric sensor in a stable manner to bony locations in the middle-ear cavity or the surrounding bone of the mastoid. Such stability can allow the piezoelectric sensor to effectively become deformed by the motion of the middle ear structure, such as the umbo with high repeatability over time. In other words, the coupling between the piezoelectric sensor and the middle ear structure, e.g., the umbo or one of the ossicles, may not be susceptible to change. In one aspect, this stability is achieved by the arrangement in that the piezoelectric sensor or its adjacent support structure contacting the umbo detects motion in a one-dimensional direction. Thus, the arrangement of the piezoelectric sensor and the supporting structures can be simplified while being stable. This approach lowers the probability of decoupling between the umbo and the sensor. Because the probability of decoupling is decreased, probability of the piezoelectric sensor slipping and scathing parts of a middle ear ossicle is reduced. Moreover, the piezoelectric sensor can detect the motion without overly mass loading and damping of the natural motion of the middle ear structure, such as the umbo.

In general, the disclosed techniques can be used to efficiently detect sound pressures by measuring vibrations of a middle ear structure, such as the umbo. The disclosed arrangements of a piezoelectric sensor and its support structures can provide stability and reproducibility while effectively detecting motion of the umbo with high signal-to-noise ratio (SNR). For example, the open circuit voltage of the piezoelectric sensor can be 0.7 μVᵣₘₛ or more for an input sound pressure of 40 dB SPL. The techniques disclosed herein can be used to extract electric signals from the piezoelectric sensor with high SNR. For example, the hearing aid device can include a sensor front-end circuit with low power consumption and amplify the extracted electric signals with high SNR. The sensor front-end circuit can consume 11 μW or less for detecting an input sound of 70 dB SPL and stimulating a subject with totally impaired cochlear function to perceive the detected sound as 70 dB SPL, which is at about the same level for a subject with normal hearing.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages will be apparent from the following detailed description, and from the claims.

### BRIEF DESCRIPTION OF THE DRAWINGS

FIG. 1 is a schematic of a cross-section of a human ear.

FIG. 2 is a schematic block diagram of components of an example of a cochlear implant described herein.

FIG. 3 is a schematic block diagram of components of an example of a middle ear implant described herein.

FIG. 4 is a schematic of an example of a piezoelectric sensor in the form of a piezoelectric cantilever design.

FIG. 5A is a schematic of an example of an arrangement including a piezoelectric sensor implanted in a middle ear cavity.

FIG. 5B is a schematic of another example of an arrangement including a piezoelectric sensor implanted in a middle ear cavity.

FIG. 6 is a schematic of an example of a sensor front-end circuit. Stage 1 is a programmable charge amplifier circuit. Stage 2 is an amplifier with an electronically-programmable gain and Stage 3 is a driver circuit to feed an analog-to-digital converter to digitize the sensed signal.

FIG. 7 is a flow chart depicting example operations for detecting motion of middle ear structures of a subject and generating electric signals using a piezoelectric sensor as described herein.

FIG. 8A is a plot showing frequency response measurements of an output of a charge amplifier circuit connected to a piezoelectric device sensing umbo motion for various sound pressure levels (SPL).

FIG. 8B is a plot showing measurements of charge amplifier output level (as in 8A) as a function of ear canal pressure (P_{EC}) to demonstrate linearity.

FIG. 8C is a plot showing measured umbo velocity (V_{UMBO}) with laser Doppler vibrometry as a function of ear canal pressure (P_{EC}) while the piezoelectric sensor was coupled.

FIGS. 9A-B are plots showing measured transfer characteristics from ear canal pressure (P_{EC}) to umbo velocity (V_{UMBO}) measured with laser Doppler vibrometry over time.

FIG. 9C is a plot showing measured umbo velocities (V_{UMBO}) with laser Doppler vibrometry of two bone samples.

FIG. 10 is a plot showing measured transfer characteristics from ear canal pressure (P_{EC}) to umbo velocity (V_{UMBO}) measured with laser Doppler vibrometry with and without loading the umbo with a piezoelectric sensor.

FIG. 11 is a plot showing measured transfer characteristics from ear canal pressure (P_{EC}) to charge amplifier output (V_{PZ}) as a function of frequency.

### DETAILED DESCRIPTION

The methods and systems described herein can be implemented in many ways. Some useful implementations are described below. The scope of the present disclosure is not limited to the detailed implementations described in this section, but is described in broader terms in the claims.

Anatomy of the Ear

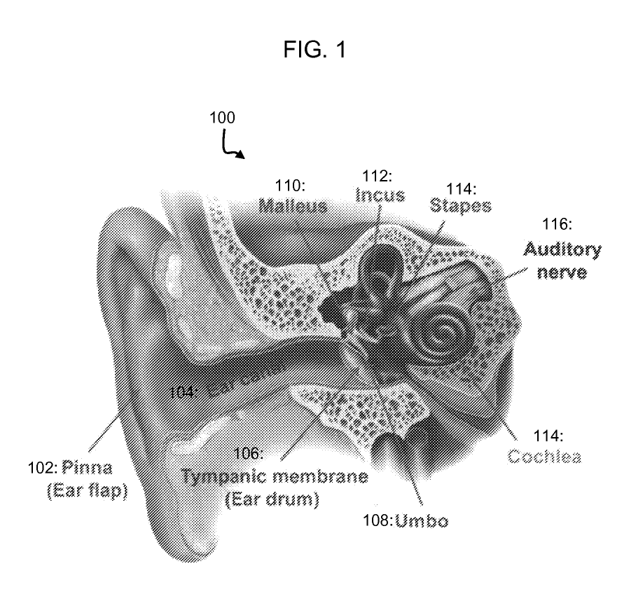

The ears of subjects, e.g., humans and animals such as mammals, have a similar anatomy. The human ear is an auditory system that transforms acoustical energy to electrical energy that is applied to the auditory nerve. FIG. 1 is a schematic of a cross section of a human ear 100, which is separated into the outer ear, middle, and inner ear.

The outer ear includes the pinna 102, ear canal 104, and tympanic membrane 106 (ear drum). Umbo 108 is the small area where the tip/end section of the manubrium of the malleus 110 is firmly attached and enveloped by the tympanic membrane at the most depressed part of the tympanic membrane when viewed from within the ear canal. Sound pressure waves enter the pinna 102, enter the ear canal 104, and vibrate the tympanic membrane 106, which motion couples to the ossicular chain that includes three small bones called the malleus 110, incus 112, and stapes 114 of the middle ear. The motion of the stapes 114 on the oval window of the cochlea moves fluid inside the cochlea of the inner ear. Motion of the hair cells of the cochlea due to the motion of the cochlear fluid generates electric pulses to the auditory nerve, which the brain interprets as sound. Higher frequency waves excite the hair cells near the base and lower frequency waves excite hair cells at the apical end of the cochlea, as the mechanical properties of the cochlear partition is tuned to different frequencies longitudinally.

Conductive hearing loss generally occurs when there is damage to the pathway of sound transmission between the environmental air and cochlea (such as occlusion of the ear canal or lesion of the ossicular chain). Sensorineural hearing loss occurs when there is damage to the hair cells in the cochlea or neurotransmission between sensory cells and the brain. In conductive hearing loss, a middle ear implant can be used to mechanically stimulate, for example, the oval window or the round window. In the latter case, a cochlear implant can be used to generate electric pulses that are applied to the auditory nerve to help restore hearing. This specification relates to middle ear implants and cochlear implants to aid hearing.

Devices

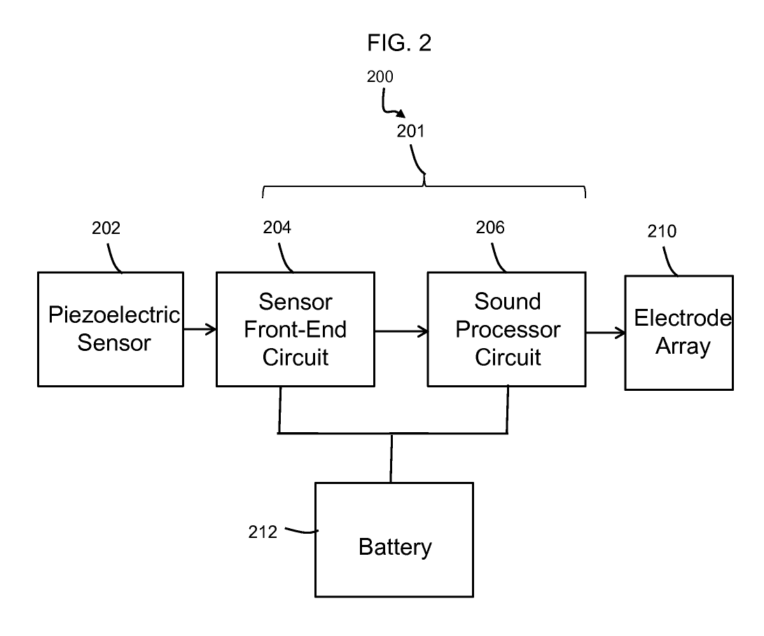

FIG. 2 is a schematic of an example of a cochlear implant 200 including a processing circuit 201, a piezoelectric sensor 202, an electrode array 210, and a battery 212. The processing circuit 201 can include components 202-206. Piezoelectric sensor 202 can be mounted to contact one of the ossicles, e.g., on the malleus, or on the umbo. As used herein, a piezoelectric sensor is any device using piezoelectric material to convert sound or vibration into an electrical signal, e.g., an analog or digital electrical signal. The piezoelectric sensor 202 can detect motion such as the motion of the umbo and generate electrical signals, which are received by sensor front-end circuit 204. The sensor front-end circuit 204 can amplify the received electrical signals and can convert analog signals into digital signals. As a result, the sensor front-end circuit 204 can send digital electrical signals to sound processor circuit 206. The sound processor circuit 206 spectrally decomposes the received signals into multiple channels. Different channels represent different spectral ranges of sound perceived by a subject. In some implementations, processing circuit 201 can include a waveform stimulator that uses the outputs of the multiple channels to control electric pulses delivered by electrode array 210. The waveform stimulator can generate waveforms that are applied to the electrode array 210 as electric pulses through an electrode switch matrix. In this way, the electric pulses can stimulate the auditory nerve of the subject according to the detected sound and processed electrical signals. Battery 212 can provide power to various components (e.g., sensor front-end circuit 204, sound processor circuit 206, waveform stimulator) of cochlear implant 200.

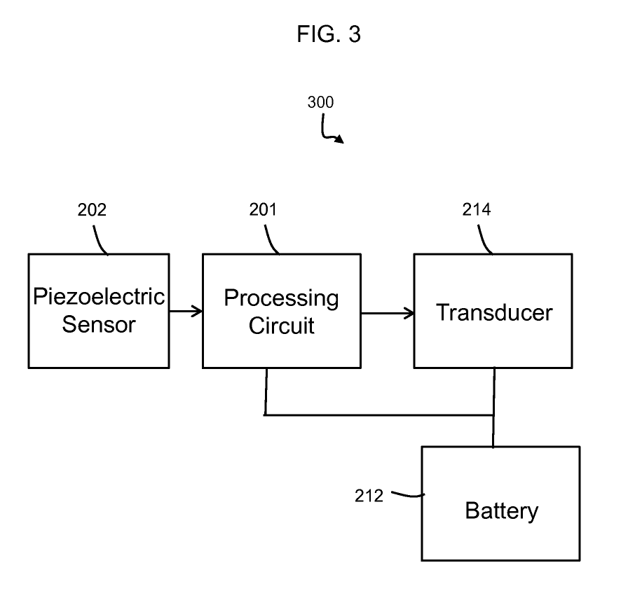

FIG. 3 is a schematic of an example of a middle ear implant 300 including a processing circuit 201, a piezoelectric sensor 202, a transducer 214, and a battery 212. The piezoelectric sensor 202 described in relation to FIG. 2, can be used for the example shown in FIG. 3. The processing circuit 201 can receive and amplify electric signals provided by the piezoelectric sensor 202. The amplified signals can be sent to the transducer 214 that mechanically stimulates the oval window or round window of the ear. The processing circuit 201 can include the sensor front-end circuit 204 described in relation to FIG. 2. In this case, the sensor front-end circuit 204 may not include an analog-to-digital converter (ADC). In some implementations, the processing circuit 201 can spectrally filter the electric signals received from the piezoelectric sensor 202. Examples of the transducer 214 include actuators such as piezoelectric and electromagnetic actuators.

Piezoelectric Sensors

A piezoelectric sensor 202 (e.g., piezoelectric sensor) is small enough to be implanted in the middle ear and to replace conventional microphones installed external to the ear. The piezoelectric sensor 202 is small and light-weight so that the presence of the piezoelectric sensor 202 does not substantially impede natural motion of the middle ear structures, e.g., tympanic membrane, middle-ear ossicles beyond an amount which is useful for sensing of sound and/or transmission of sound via the cochlear chain. In other words, the mass-loading by the sensor may be designed to be negligible if the sensor is implanted to contact one of the bones in the ossicular chain or the ear drum so as to avoid performance reduction of the ossicular chain, or may be designed such that the mechanical loading is not so significant as to unduly impede sensing of the sound by the sensor and/or transmission of sound by the cochlear chain. Moreover, the piezoelectric sensor 202 can be mechanically impedance matched to effectively pick up sound waves by vibration of the bones, e.g., the malleus.

The piezoelectric sensor 202 has the sensitivity, dynamic range (e.g., 50 dB or more), and frequency bandwidth needed for hearing. This is taken into consideration in the design of the piezoelectric sensor 202 and sensor front-end circuit 204. Moreover, the electrical impedance between the piezoelectric sensor 202 and the sensor front-end circuit 204 can be matched so the sensor front-end circuit 204 can efficiently receive electrical charge from the piezoelectric sensor 202, thereby increasing the sensitivity. In some implementations, the piezoelectric sensor 202 can detect sounds from 300 Hz to 10 kHz over a 50 dB dynamic range from 40 to 90 dB SPL. In some implementations, a pre-emphasis of +6 dB/octave can be embedded in the output of piezoelectric sensor 202. Generally, the piezoelectric sensor 202, depending on its composition, can detect frequencies from 10 Hz to 60 kHz or more (e.g., 50 Hz to 50 kHz, 100 Hz to 20 kHz, or 200 Hz to 10 kHz), and electrical signals with such frequencies can be processed by a processing circuit of a hearing aid to generate stimulus signals (e.g., mechanical vibrations, electric pulses) corresponding to these frequencies.

Piezoelectric sensor 202 can be designed to have a noise floor level to provide sufficient signal-to-noise and sensitivity, and stiffness that does not significantly deter the function of the middle ear structures such as the tympanic membrane or ossicles. To determine the effect of the piezoelectric sensor on the normal middle-ear motion, laser Doppler vibrometery (LDV) can be used to measure the vibration velocity of the location to which the piezoelectric sensor will be mounted, e.g., on the umbo. For example, for pure tones from 0.1 to 19 kHz sound input, the integrated noise is about 10 μgᵣₘₛ (1 g=9.8 m/s²) over 8 kHz bandwidth and a minimum detectable sound of 40 dB SPL leads to a noise floor of about 0.1 μgᵣₘₛ/sqrt(Hz). The noise of piezoelectric sensor 202 can be lower than this noise floor of 0.1 μgᵣₘₛ/sqrt(Hz).

The piezoelectric sensor 202 can be a piezoelectric sensor, for example, made from Lead-Zirconate-Titanate (PZT), Aluminum Nitride (AlN), Zinc Oxide (ZnO), or Polyvinylidene fluoride (PVDF). The piezoelectric sensor 202 can be made from two or more layers of piezoelectric materials. In some implementations, the piezoelectric sensor 202 can be made from a single layer of piezoelectric material.

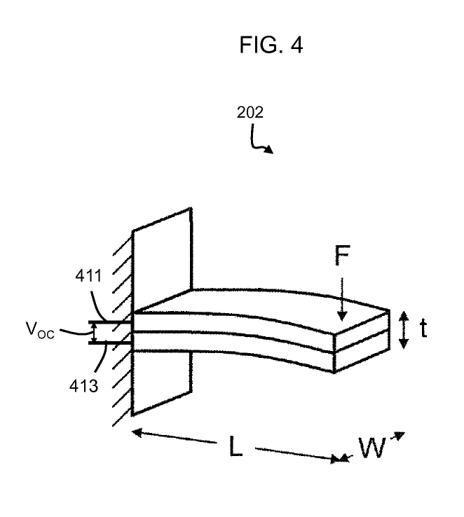

FIG. 4 is a schematic of an example of the piezoelectric sensor 202 (e.g., piezoelectric sensor) made from piezoelectric material, which is clamped on one end like a cantilever. The other end can be placed in contact, e.g., with the umbo or elsewhere along the middle-ear ossicles in the middle ear cavity. For example, when a piezoelectric sensor is in contact with the umbo, and when the umbo vibrates, the umbo exerts a force F on the sensor as illustrated in FIG. 4. Similarly, when in contact with any part of an ossicle, force F can be exerted from the ossicle. As the force F bends the piezoelectric sensor 202, an open circuit voltage V_{OC} is generated across two terminals 411 and 413 of the piezoelectric sensor 202 according to equation 1 (Eq. (1)):

$${V}_{OC} = {g}_{31} ( \frac{3 L}{2 Wt} ) F = {g}_{31} ( \frac{3 L}{2 Wt} ) {mA}_{U} ( f ) {P}_{EC} \qquad ( 1 )$$

where W, L, and t are dimensions of sensor depicted in FIG. 4. g₃ᵢ is the piezoelectric transverse voltage coefficient, which for example, can be about −11.6×10⁻³V·m/N for typical piezoelectric materials. For example, force F applied by an umbo can be calculated from the ear canal pressure P_{EC} according to the relation F=mA_{U}(f)P_{EC}, where m is the mass of piezoelectric sensor 202 and A_{U}(f) is the umbo acceleration normalize by P_{EC}. Typically, A_{U}(f) is about 1 to 2 m/s²/Pa.

In the example illustrated in FIG. 4, the piezoelectric sensor 202 made from piezoelectric material has W=3 mm, L=3 mm, and t=0.5 mm. Using density 7800 kg/m³ of the PZT, mass m of the piezoelectric sensor 202 can be calculated to provide V_{OC} ranging from 0.7 μVᵣₘₛ to 2.4 μVᵣₘₛ for sound pressure levels from 40 to 90 dB SPL. Such range of V_{OC} is sufficiently larger than noise so as to be detected by sensor front-end circuit 204. Generally, the piezoelectric sensor 202 can be cut in other dimensions and shapes with selected mass than described in relation to FIG. 4. In some implementations, wires connected to the piezoelectric sensor 202 can be shielded and/or the sensor front-end circuit 204 can be placed close to the sensor with a wire connection length of 10 mm or less (e.g., 15 mm or less, 20 mm or less), thereby reducing any electromagnetic interference affecting the piezoelectric sensor 202.

A piezoelectric sensor can be made from a composite piezoelectric material including, for example, piezoelectric ceramics and polymers. For instance, pillars of ceramic piezoelectric can be embedded in a continuous layer of polymer. The pillars can be electrically connected to each other so that voltages generated by bending of the pillars can be collected through output terminals of the piezoelectric sensor. In some implementations, an electrode (e.g., nickel electrode) can be formed on one side of the piezoelectric sensor (which can be shaped as a bar, flat disc, or flat sheet) to act as a terminal.

In some implementations, a piezoelectric sensor can be a composite of piezo material and plastic such as polyvinylidene fluoride (PVDF). The composition can be controlled to adjust the stiffness of the piezoelectric sensor to match the impedance of the umbo, e.g., to limit the loading of the umbo and/or ossicular chain to an acceptable level. The goal is to capture acoustic energy to maximize sensing by the sensor by loading the ossicular chain only enough to adequately sense sound and not load it more than allows the sound to pass along the ossicular chain.

Likewise, one may control loading by the structure of the piezo-electric element such as by stacking the structure. One may design the sensor to load the ossicular chain only enough to adequately sense the sound (to generate adequate output of the sensor) but not more, and certainly not load the ossicular chain to an extent that transmission and/or sensing of sound is substantially impeded.

Generally, a piezoelectric material can generate an output voltage not necessarily from bending but from other forms of deformation including contraction and elongation.

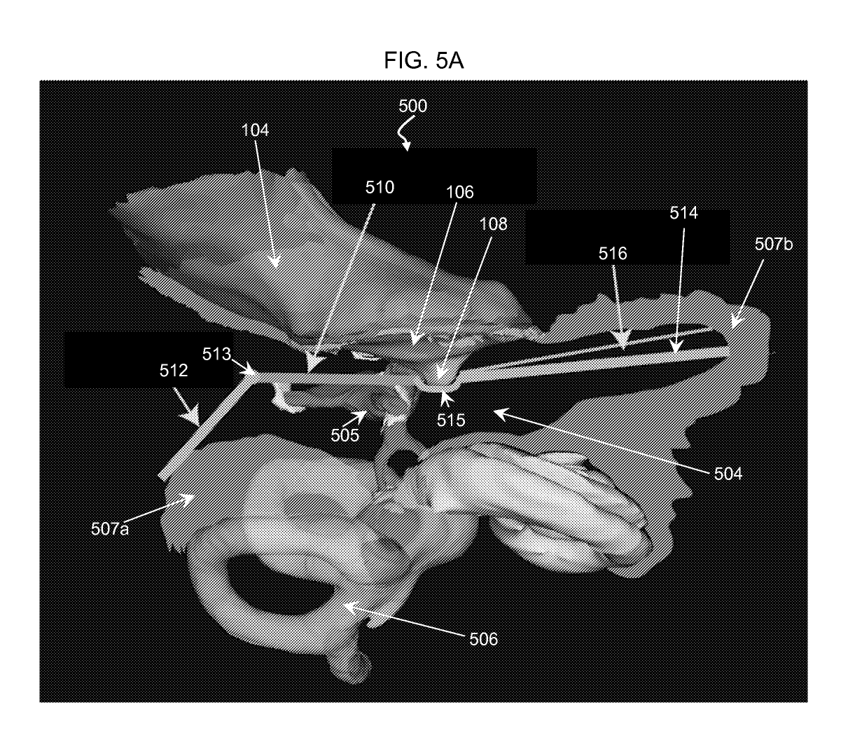

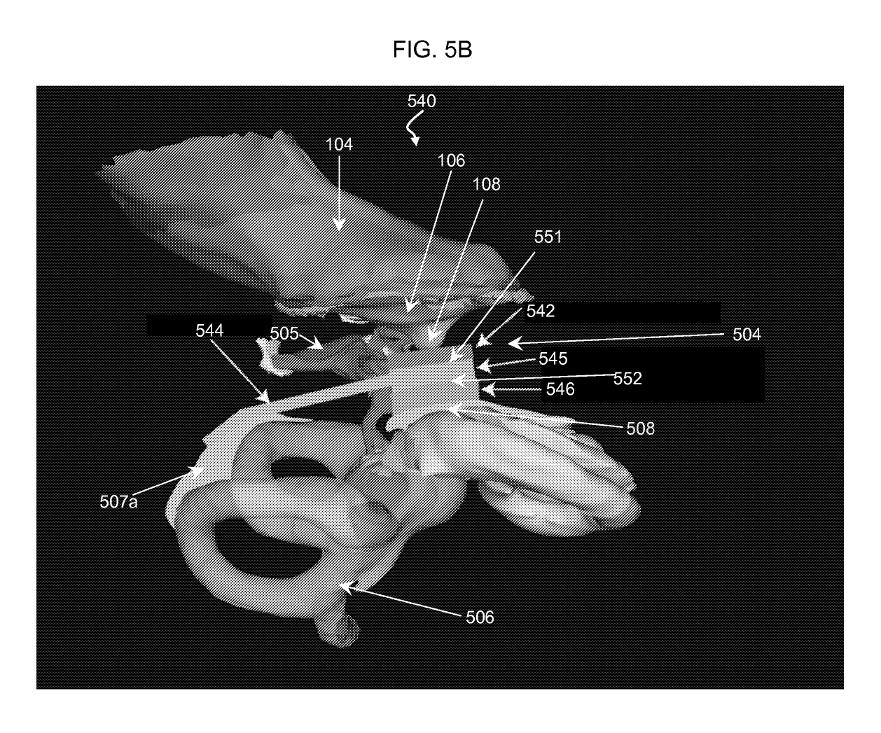

When the piezoelectric sensor 202 in FIG. 4 includes a piezoelectric sensor, a support structure, e.g., in the form of an elongated beam, can be used to fix one end of the piezoelectric sensor to a bony wall of the middle ear (507b in FIG. 5A) or to the mastoid bone (507a in FIG. 5A) for securing and stabilizing the fixed end of the piezoelectric sensor.

To the free end of the piezoelectric sensor (such as 202 in FIG. 4), an elongated metal structure (similar to a beam, needle, or rod) can be fixed (e.g., using a tissue-safe adhesive). This needle/rod can act as a lever and can be more compliant than the piezoelectric material (e.g. PZT), and the non-attached end of the needle/rod can directly contact a middle ear structure such as the umbo. The tip of this needle/rod can be shaped to couple the interfacing area of the ossicle for stability. Vibration motion of the structure is transferred through the needle/rod to the piezoelectric sensor 202. In this case, the piezoelectric sensor 202 is not directly in contact with any of the middle ear structures. The needle/rod can be a thin bar made from metal (e.g. titanium), plastic, or ceramic that is sufficiently rigid to effectively transfer vibrations to the sensor yet sufficiently compliant to allow for near-normal motion of the ossicles.

Piezoelectric sensor 202 can have numerous advantages such as having a small size, mass, customizability (by being cut in any shape and size), low-power operation, and high sensitivity required for detecting sound pressures less than 60 dB SPL. Unless the sensor includes ferromagnetic parts, the piezoelectric sensor 202 can remain implanted in the subject, and would be safe during magnetic resonance imaging (MRI).

FIG. 5A is a schematic of an example arrangement 500 including a piezoelectric sensor 510 implanted in a middle ear cavity 504 to detect vibrations of the umbo 108. In this example, the piezoelectric sensor 510 is supported by anchor structure 512 laterally and support structures 514 and 516 medially. Anchor structure 512, can be secured, e.g., screwed and/or glued, onto mastoid bone 507a. The element labeled 505 is the ossicle and the element labeled 506 is a semicircular canal. Adhesives such as fibrin glue or N-butyl-2-cyanoacrylate can be used to adhere the support structure to mastoid bones 507a or bony medial walls 507b of the middle ear cavity. Generally, the support structures and anchor structures can have an elongated shape such as in a rod or beam, which are elongated in their longitudinal direction.

In some implementations, the piezoelectric sensor 510 can be shaped as a bending bar or a strip. For example, the piezoelectric sensor 510 can have the same or similar dimensions of the example described in relation to FIG. 4 and with a mechanical impedance that is matched with that of the umbo. This approach can reduce load on the umbo and reduce change of the natural umbo motion by the loading of the piezoelectric sensor. Moreover, harmonic distortion of detected sound signals can be reduced. In some implementations, piezoelectric sensor 510 can have an elongated shape such as a slab or a rod, for example, as shown in FIG. 4.

The anchor structure 512 can be fixed on its one end onto mastoid bone 507a. Its other end can include a ball joint 513 that is used to adjust the angle between the piezoelectric sensor 510 extending towards the umbo 108 and the length of the anchor structure 512. Thus, the region of its one end is fixed onto mastoid bone 507, and the region is located away for the other end including the ball joint 513. In addition, the length of the support structure 512 can be selected in a range of 2-3 mm (e.g., 3-4 mm, 4-5 mm) and angle of the piezoelectric sensor 510 relative to the support structure 512 can be adjusted by the ball joint 513 to position the piezoelectric sensor 510 to couple to the umbo 108. The end of the ball joint 513 can be glued or otherwise secured onto one end of the piezoelectric sensor 510. This end of the piezoelectric sensor 510 can have two terminals 411 and 413 as described in relation to FIG. 4. The other end of the piezoelectric sensor 510 can be glued or otherwise secured onto tip portion 515 of the anchor structure 514, which other end is fixed onto the bony medial wall 507b. Another support structure 516 (in addition to 514) can be used to further stabilize the piezoelectric system. The stabilizing structure(s) (516 and/or 514) should be stiff enough to provide stability, but compliant enough to allow for near-normal umbo motion.

The support and anchor structures and techniques for stably holding piezoelectric sensor 510 can be implemented to have the piezoelectric sensor 510 to measure motion of middle ear structures such as the umbo (or a different part of an ossicle), either by direct contact of such structures or by contact through support structures. In addition, the support or stabilizing structures 514 and 516 may not be necessary, however, the cup-shaped tip portion 515 needs to be attached to the piezoelectric device 510 to prevent the sensor from slipping away from the umbo).

The tip portion 515 couples to the umbo 108, and is attached to the piezoelectric device 510. This piezoelectric tip portion 515 can be made from a light stiff material (e.g. plastic, titanium). Because the piezoelectric sensor 510 is held by the anchor structure 512 on one end and connected to the tip portion 515 on the other end, the motion of the tip portion 515 can apply a force to, for example, bend the piezoelectric sensor 510. Then, as described in relation to the embodiment shown in FIG. 4, the piezoelectric sensor 510 can form an open circuit voltage that provides electric signals to a processing circuit 201 through a wired connection. Because the umbo generally has the greatest displacement motion along the middle-ear ossicular chain for a wide frequency range, the piezoelectric sensor 510 can effectively generate large electric signals from the motion of the umbo compared to when the piezoelectric sensor 510 detects motion at other parts of the middle-ear ossicular chain.

In some implementations, the tip portion 515 can be formed to accommodate the shape of the umbo 108 and encompass (e.g., like a cup to wrap around the bottom of) the umbo 108. For example, the tip portion 515 can wrap around (e.g., for 360°) the umbo 108. Such an approach can increase the stability of the piezoelectric sensor 510 and increase the repeatability of the piezoelectric sensor 510's response over time. In some implementations, the stabilizing structures 514 and 516 may not be necessary. In this case, the tip portion 515 is only attached to the piezoelectric sensor 510.

Another implementation can have the piezoelectric sensor 510 directly contacting the umbo 108, if it is formed in the shape of the umbo 108 to encompass the umbo 108 in a similar manner describe for tip portion 515. Moreover, typically, the shape of the bottom of an umbo (tip of the manubrium) does not significantly vary among different subjects unlike some other parts of the middle ear ossicles (e.g. malleus head, stapes, incus body and long process of the incus, etc.). For this reason, the response (e.g., velocity and impedance) of an umbo can be relatively highly predictable compared to the other parts. Therefore, one design of a piezoelectric sensor and shape of the tip portion can be used for different subjects. Variations such as different sizes of middle ear cavity over different subjects can be adjusted using the support structures disclosed herein.

When piezoelectric sensor 510 is implemented to measure motion of a particular part of any middle ear ossicle, tip portion 515 or one end of the piezoelectric sensor 510 can be shaped in a similar manner described above to match the outer surface of a respective middle ear structure being measured.

FIG. 5B is a schematic of another example arrangement 540 including a piezoelectric sensor 542 implanted in a middle ear cavity 504 to detect vibrations of umbo 108. In this example, piezoelectric sensor 542 is shaped as a plate (e.g., disc). For example, the plate can be shaped as a cylindrical disc that bends or is compressed due to motion of the umbo 108. One side of the piezoelectric plate directly contacts the umbo 108 and the other side of the plate is supported by an extension 545 of support structure 544. The extension 545 can be hollow and cylindrically shaped to hold the rim of the piezoelectric disc 542 in a stable manner, yet allowing for the bending of the disc 542. The outer rim of the piezoelectric plate 542 can be fixed to the extension 545. The extension 545 has a first surface 551 that faces towards the piezoelectric sensor plate 542. On the opposite side the extension 545 has a second surface 552 that faces towards the promontory 508 of the surrounding bone of the cochlea. Different ears can have different distances between the umbo 108 and the cochlear promontory 508. To accommodate these differences, one or more additional base elements 546 can be coupled to the second surface 552 of the extension 545 and fixed to the promontory 508 (surrounding bone of the cochlea) or the thickness of a single base element 546 can be selected according to the distance between the umbo 108 and the cochlear promontory 508. In some implementations, the second surface 552 may be fixed directly to the promontory 508. Some systems may further incorporate additional mechanical fixtures to preload the piezoelectric element to a desirable mechanical position or loading point.

In some implementations, the base elements 546 can be made of or include compliant medical-grade silicon and/or bone cement at the interface of the promontory bone to conform to the shape of the cochlear promontory 508 and increase stability. The piezoelectric plate 542, the extension 545 of support structure 544, and the base element 546 can all be fixed, e.g., glued, to each other through their contact surfaces. In addition, the end of support structure 544 opposite extension 545 is glued and/or screwed onto mastoid bone 507a. In some implementations, the piezoelectric sensor plate 542 can be shaped or include a buffer element (not shown) that is shaped as the umbo 108 (and located between the umbo 108 and the sensor plate 542) in a similar manner described in relation to FIG. 5A.

The described techniques for support structure 544 and base element 546 for stably holding piezoelectric sensor 542 can be implemented to have the piezoelectric sensor plate 542 to measure motion of middle ear structures such as the eardrum or one of the ossicles, either by direct contact of such structures or by contact through the support structures. In this case, support structure 544 can be fixed to a different part of mastoid bone 507a so that the piezoelectric sensor plate 542 can contact, for example, other ossicles.

In various implementations, the support structures 512, 516, 544 and anchor structure 514 can be made from materials such as metals, including titanium or stainless steel, composites, or plastics. The support structures can stabilize the position of the piezoelectric sensors 510 and 542.

The disclosed techniques can allow the implemented piezoelectric sensors to generate a relatively large electric signal by measuring motion of the umbo compared to cases where sensors measure other parts of the middle ear. This is because the region of the umbo is most distal from the axis of rotation of the middle-ear ossicles at low frequencies and generally has the greatest displacement motion along the middle-ear ossicular chain. Moreover, the umbo can generally be considered to have a one-dimensional motion—the deflection of the sensor and support or anchor structures can be parallel to or in line with the deflection of the umbo—and the piezoelectric sensor or its adjacent support or anchor structure contacting the umbo need only to detect motion in this one-dimensional direction. Although most of the middle-ear ossicles have complex modes of motion at higher frequencies, the umbo generally has a simple mode of motion that can be sensed by a piezosensor as proposed. Thus, the arrangement and the piezoelectric sensor and the supporting structures can be simplified while being stable. This approach lowers the probability of decoupling between the umbo and the sensor. Because the probability of decoupling is decreased, probability of the piezoelectric sensor slipping and scathing parts of the middle ear cavity is reduced. On the other hand, some conventional sensors are mounted on locations with less magnitude of motion and the direction of motion sensed by the sensors can vary with frequency and be inconsistent over different ears. In particular, when the conventional sensors are not in line with motion of the detected location of the middle ear, the sensors can decouple with the detected location, and significantly change the natural middle-ear motion of the detected location.

The disclosed techniques and arrangements can allow access to an umbo within a narrow opening. During implantation of conventional sensors, extra drilling to expose area of the ossicles may be unnecessary (e.g., compared to a cochlear implant or active middle-ear implant) because the umbo is visible and accessible in the middle-ear cavity via the opening of the facial recess. This is not the case for some other types of conventional sensors that rely on extra exposure, such as the epitympanum.

Sensor Front-End Circuit

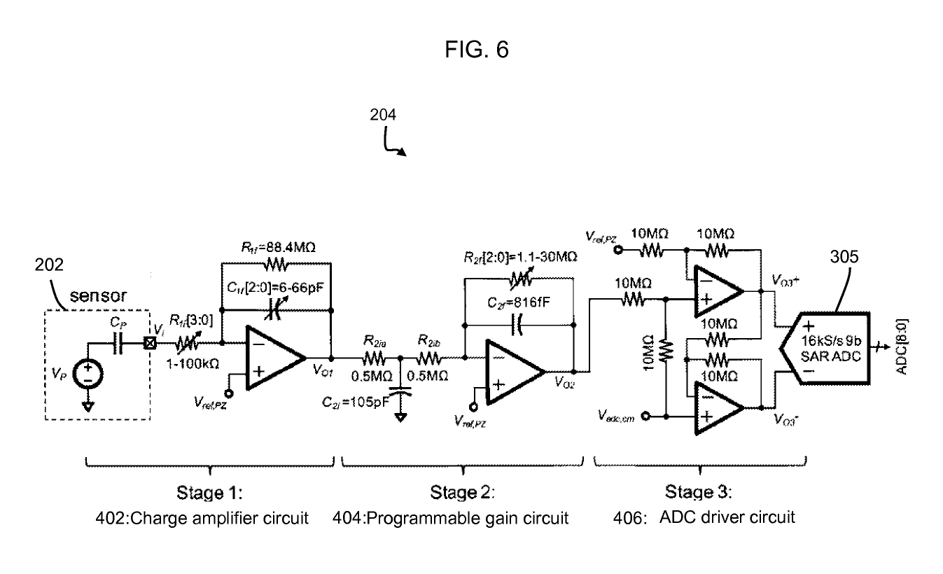

FIG. 6 is a schematic of an example of sensor front-end circuit 204 that can be included in a processing circuit 201 for a cochlear implant 200 or a middle ear implant 300. The sensor front-end circuit 204 can operate from a 1.5 V analog power supply, and includes three stages and an analog-to-digital converter (ADC) 305. The middle ear implant 300 may not need the ADC 305. Stage 1 includes a charge amplifier 402 that is electrically connected to piezoelectric sensor 202. Stage 2 includes a programmable gain circuit 404, and stage 3 includes a single-ended to differential ADC driver circuit 406. The sensor front-end circuit 204 provides a mid-rail reference voltage V_{ref,PZ} to bias one terminal (e.g., terminal 413) of piezoelectric sensor 202. The other terminal (e.g., terminal 411) of piezoelectric sensor 202 is connected to an input of the charge amplifier circuit 402 as shown in FIG. 6. The ADC driver circuit 406 provides analog level conversion from V_{ref, PZ}=750 mV down to V_{adc,cm}=300 mV, which is the input common-mode for ADC 305. In an example, the ADC 305 can be a differential 16 kS/s 9-bit SAR ADC operating from a 0.6 V power supply. The sensor front-end circuit 204 can be electrically impedance matched to a piezoelectric sensor 202 so that the processing circuit 201 can amplify electric signals provided by the piezoelectric sensor 202 with high SNR. Moreover, the disclosed techniques enable the sensor front-end circuit 204 to operate with low power consumption. For example, the charge amplifier 402 can consume power of 6.75 μW or less, the programmable gain circuit 404 can consume power of 1.37 μMI or less, and the ADC driver circuit 406 can consume power of 2.14 μW or less for detecting an input sound of 70 dB SPL and stimulating a subject with totally impaired cochlear function to perceive the detected sound as 70 dB SPL, which is at about the same level for a subject with normal hearing.

In stage 1, charge amplifier circuit 402 can include resistors R₁ᵢ and R_{1f}, variable capacitor C_{1f}, and an operational amplifier (op-amp), e.g., as shown in FIG. 6. Resistor R₁ᵢ can be a variable resistor with a resistance value ranging from 1 to 100 kΩ. Piezoelectric sensor 202 can include a capacitor Cₚ, which can have values from 0.2 nF to 3 nF. Accordingly, C_{1f} can be a tunable capacitor with values small enough (e.g., 6-66 pF) to provide sufficient gain for small values of Cₚ, and large enough to limit the gain for large values of Cₚ so as not to saturate the charge amplifier circuit 402 response at large sound pressure levels. C_{1f} can be a feedback capacitor being a 3-bit switched-capacitor and is non-uniformly spaced to provide programmable mid-band gain in 3 dB steps. R_{1f} is constrained by the minimum value of C_{f} and is set to 88.4 MΩ R₁ᵢ can be implemented as a 4-bit switched-resistor logarithmically spaced from 1 kΩ to 100 kΩ.

For the piezoelectric sensor 202 described in relation to FIG. 4 with W=3 mm, L=3 mm, and t=0.5 mm, the minimum signal is about 3 μVᵣₘₛ at 40 dB SPL, which sets an upper bound of noise of the sensor front-end circuit 204. The noise from R₁ᵢ and R_{1f} are reduced for larger values of Cₚ, and the noise from the op-amp can be independent of Cₚ. The noise from R_{1f} is negligible because of its relatively large value of 88.5 MΩ than R₁ᵢ. For Cₚ=0.5 nF and 3 nF as examples, the total noise of the charge amplifier circuit 402 is about 2.5 μVᵣₘₛ and 1.7 μVᵣₘₛ, respectively.

The op-amp in the charge amplifier circuit 402 can be a folded-cascode op-amp with source-degenerated bias transistors to improve noise performance Input devices of the op-amp can be p-type metal-oxide-semiconductor (PMOS) transistors with large pair dimensions to limit 1/f noise so that the op-amp noise is dominated by thermal noise. The op-amp utilizes a common-source stage to increase its open loop gain, and the output of the op-amp is a PMOS source-follower with low output impedance to drive the resistive load of stage 2 of the sensor front-end circuit 204.

For stage 2, the programmable gain circuit 404 can include several resistors, a capacitor, and op-amp, e.g., as shown in FIG. 6. In this example, R₂ᵢₐ and R_{2ib} are each 0.5 MΩ, Ref is a switch-resistor that is logarithmically spaced between 1.1 and 30 MΩ to provide programmable gain in 6 dB steps from 0.83 dB to 29.5 dB. Capacitor C_{2f} has a value 816 fF. In some implementations, the programmable gain circuit 404 is a 2-pole programmable gain-amplifier (PGA) to provide gain in addition to that of charge amplifier circuit 402. Op-amp of the programmable gain circuit 404 is a cascaded current mirror op-amp to achieve high gain. Its output stage is a PMOS source-follower to provide low output impedance to drive the resistive load by stage 3 of the sensor front-end circuit 204. The noise of the programmable gain circuit 404 can decrease with larger values of Ref.

Stage 3 of the sensor front-end circuit 204 includes an ADC driver circuit 406, e.g., as shown in FIG. 6. In this example, the ADC driver circuit 406 is a single-ended to differential amplifier that is configured to drive the input capacitance of ADC 305, which is about 480 fF. This can be achieved by implementing a series connection of a non-inverting amplifier (e.g., gain=2) and an inverting amplifier (e.g., gain=−1). In this way, the ADC driver circuit 406 can provide an additional gain of 12 dB (4V/V). The two op-amps used in stage 3 are two-stage op-amps that leverage the cascoded current mirror stage of the op-amp in the programmable gain circuit 404, with a high-power common-source output stage to drive the capacitance of ADC 305. Because the ADC 305 operates from a low supply voltage of 0.6 V, stage 3 can provide analog level conversion from V_{ref,PZ}=750 mV to the ADC input common-mode of V_{adc,cm}=300 mV. This can be achieved by biasing of the feedback network of 10 MΩ resistors.

General Methodology

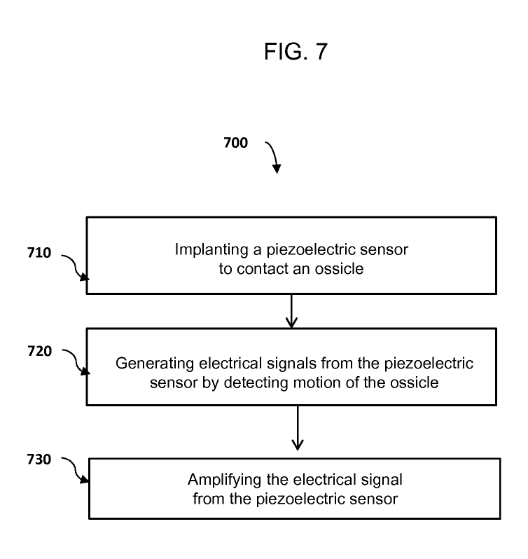

Flow chart 700 in FIG. 7 depicts examples of steps for detecting motion of middle ear structures such as the umbo (where the end of the manubrium of the malleus is attached to the center of the eardrum and encompassed by the layers of the eardrum) of a subject and generating electric signals using a piezoelectric sensor 202. In this example, the piezoelectric sensor 202 includes a piezoelectric sensor and one or more support structures.

Surgical procedures are used to implant the piezoelectric sensor 202 to contact an ossicle, e.g., at the umbo (step 710) within the middle ear cavity. In some implementations, the piezoelectric sensor 202 can be surgically implanted without drilling further areas, because the umbo is already visible. The one or more support and anchor structures can be fixed on the mastoid bone or medial walls of the middle ear cavity to support the piezoelectric sensor. The support and anchor structures or the piezoelectric sensor can directly contact the middle ear structures such as the umbo, or another ossicle. In some implementations, portion of the support or anchor structure or the piezoelectric sensor contacting the middle ear structure can be formed as a shape of the contacting structure to increase stability. For example, the portion can be formed in a shape of the surface (facing the middle-ear cavity) of the umbo while encompassing the umbo.

Subsequent steps include generating electric signals from the piezoelectric sensor 202 by detecting motion of the middle ear structure such as an ossicle (step 720). The motion of the middle ear structure can apply a force on the piezoelectric sensor so as to bend the piezoelectric sensor. This motion leads to formation of voltage across the piezoelectric sensor, and the voltage can generate electric signals that are output from the piezoelectric sensor.

Next, a processing circuit 201 including a sensor front-end circuit 204 receives and amplifies the electric signals generated by the piezoelectric sensor (step 730). The sensor front-end circuit 204 can be electrically impedance matched to piezoelectric sensor 202 to efficiently collect current from the piezoelectric sensor 202. The sensor front-end circuit 204 can amplify the signal.

In some implementations, when the piezoelectric sensor 202 is used in a cochlear implant, the amplified signals can be converted to digital signals. A sound processor circuit 206 can spectrally decompose the converted electric signals to generate decomposed information for multiple channels of the sound processor circuit 206. Different channels represent different frequencies of sound. The decomposed signal can be further processed (e.g., extraction of envelope, compression, and fitting) and then be used to apply electric stimulus pulses to auditory nerves of the subject.

In some implementations, when the piezoelectric sensor 202 is used in a middle ear implant, the amplified signals can be input into an actuator that mechanically stimulates the proximal chain of the disarticulated middle ear (e.g., stapes), oval window or round window of the subject. The amplified signals can be further processed (e.g., spectrally filtered) before being input into the transducer. This approach can be taken to adjust the spectra of the amplified signals according to the spectral response of a transducer 214.

General Applications

The disclosed techniques can be used to implement fully implantable hearing aids such as active middle ear, cochlear implants, and auditory brainstem implants for assisting hearing in subjects with conductive hearing loss or sensorineural hearing loss. The hearing aids can utilize a piezoelectric sensor such as a piezoelectric sensor that detects motion of middle ear structures such as the umbo or movement of any other part of one of the ossicles. For example, the sensor can be impedance matched to the detected middle ear structure to maximize the signal of the sensor or made compliant to allow for the natural extent of ossicular motion to be substantially achieved. Because the motion of the umbo is generally largest among other parts of the middle-ear ossicles, and the piezoelectric sensor can be impedance matched to the umbo or manufactured to prevent loading the umbo motion, the piezoelectric sensor can efficiently detect incoming sound pressures that vibrate the umbo and generate electric signals with high SNR.

As disclosed herein, the hearing aids can be fully implantable and contained inside the ear so that subjects can use the aids in the shower and during water sports. The low-power design of the processing circuit can reduce power consumption of the hearing aids and extend the time before charging is needed.

### Examples

The methods and systems described herein are further illustrated using the following examples, which do not limit the scope of the claims.

### Piezoelectric Sensor for Detection of Umbo Motion

The performance of a middle ear mounted piezoelectric sensor detecting motion of an umbo was measured. Sound pressures with frequencies ranging from 0.1 kHz to 19 kHz were provided using a signal generator and an audio amplifier. The speaker was connected to a coupler that funneled the sound into the ear canal of a fresh (previously frozen) human cadaveric temporal bone specimen. Ear canal pressure (P_{EC}) was measured by an ER-7C probe microphone (also connected to the coupler). From the ear-canal side, the motion velocity (V_{UMBO}) of the umbo at the apex of the tympanic membrane (where the tip of the manubrium is fixed to and enveloped by the tympanic membrane) was measured using a Laser Doppler Vibrometer. A needle (lever) coupled to a ceramic piezoelectric device interfaced the umbo from the middle-ear side to sense motion of the umbo. One terminal of the piezoelectric sensor was biased at a reference voltage (e.g., ground voltage), while the other terminal was connected to the input of a charge amplifier circuit 402 of a processing circuit 201.

The temporal bone was held in place by a holder, and a needle was epoxied to the piezoelectric sensor and extended towards the umbo. Vibration of the umbo was transferred through the needle to the piezoelectric sensor. Characteristics of ear canal pressure (P_{EC}), the umbo velocity (V_{UMBO}), and the sensor output (V_{PZ}) were measured. For example, two different human temporal bones labeled “bone 096” and “bone 098” were used in the measurements.

These techniques can be implemented to measure and characterize motion of other middle ear structures such as other parts of the ear drum or one of the ossicles.

Linearity of Response

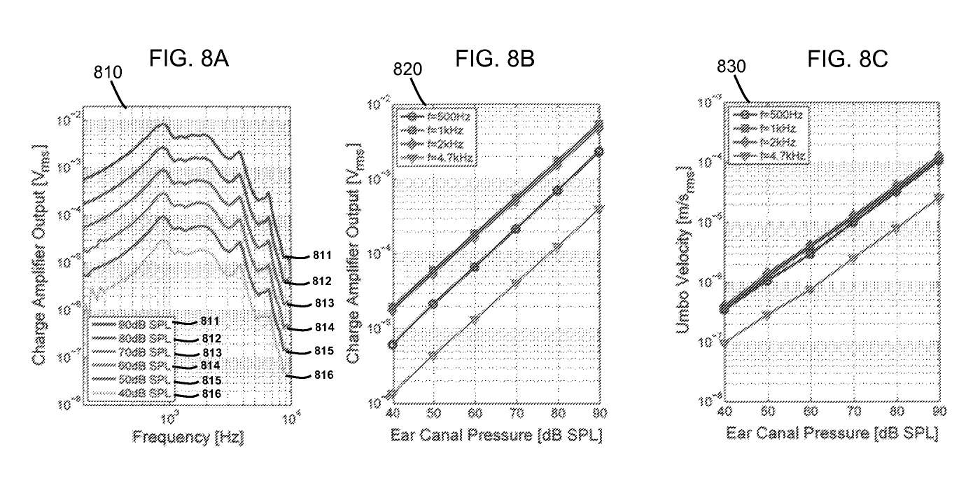

FIG. 8A is a plot 810 showing the output of the charge amplifier circuit 402 for sound pressure levels (SPL) from 40 to 90 dB SPL in the ear canal of bone 098. Curves 811-816 correspond to sound pressure levels of 90, 80, 70, 60, 50, and 40 dB SPL, respectively. Typical conversational speech ranges from 45 to 75 dB SPL and that the dynamic range of speech is about 50 dB. The results in plot 810 show that the implemented piezoelectric sensor covers the dynamic range of 50 dB while providing charge amplifier output levels of more than 10 μVᵣₘₛ around 1 kHz. The piezoelectric sensor showed sufficient performance in terms of sensitivity and dynamic range to cover typical conversational speech.

FIG. 8B is a plot 820 showing the charge amplifier output level as a function of ear canal pressure (P_{EC}). Circular markers correspond to frequency at 500 Hz, square markers correspond to frequency at 1 kHz, diamond markers correspond to frequency at 2 kHz, and triangular markers correspond to frequency at 4.7 kHz. The curves extended by each type of marker show the linearity of the charge amplifier output as a function of ear canal pressure (P_{EC}). This result shows that the piezoelectric sensor can detect sound pressures in a linear manner as a function of input sound intensity. The linearity can have a variation of slope with less than 5% (e.g., less than 3%).

FIG. 8C is a plot 830 showing the umbo velocity (V_{UMBO}) as a function of ear canal pressure (P_{EC}). Circular markers correspond to frequency at 500 Hz, square markers correspond to frequency at 1 kHz, diamond markers correspond to frequency at 2 kHz, and triangular markers correspond to frequency at 4.7 kHz. The curves extended by each type of marker show the linearity of the umbo velocity (V_{UMBO}) as a function of ear canal pressure (P_{EC}).

Repeatability and Umbo Loading

The repeatability of the piezoelectric sensor readout was measured over time for the two temporal bones, bone 096 and bone 098.

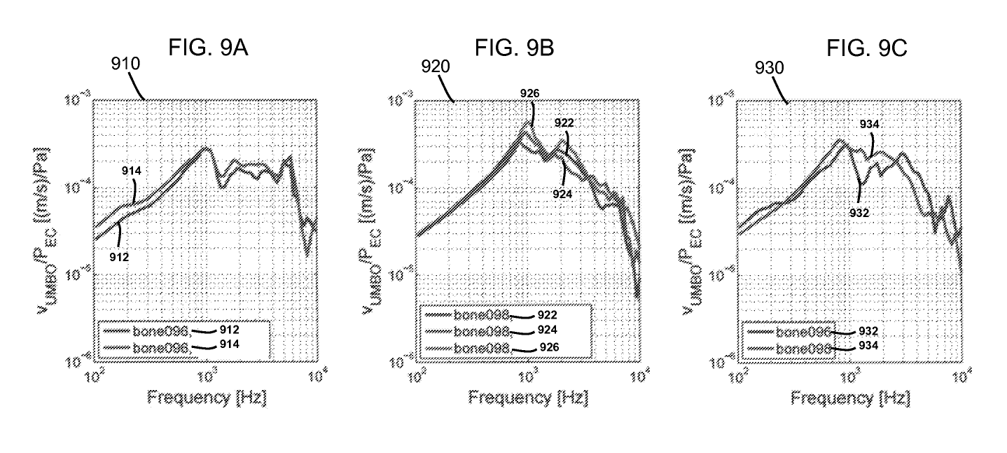

FIG. 9A is a plot 910 showing measured transfer characteristics from ear canal pressure (P_{EC}) to umbo velocity (V_{UMBO}) for bone 096 measured twice over 4 days. One measurement is represented by curve 912 and the other measurement is represented by curve 914. FIG. 9B is a plot 920 showing measured transfer characteristics from ear canal pressure (P_{EC}) to umbo velocity (V_{UMBO}) for bone 098 measured three times over the course of 20 months. One measurement is represented by curve 922, another measurement is represented by curve 924, and another measurement is represented by curve 926. The results in plots 910 and 920 show that a piezoelectric sensor has good repeatability over both short and long term periods of time. The low-frequency response of results from bone 096 varied by only a few dB, and the peak of the velocity for bone 098 shifted less than a few dB over time.

FIG. 9C is a plot 920 showing the comparison between the umbo velocity (V_{UMBO}) of the two bone 096 and bone 098. Curve 932 represents the umbo velocity of bone 096 and curve 934 represents the umbo velocity of bone 098. The two curves 932 and 934 are similar despite being measured from two different specimens.

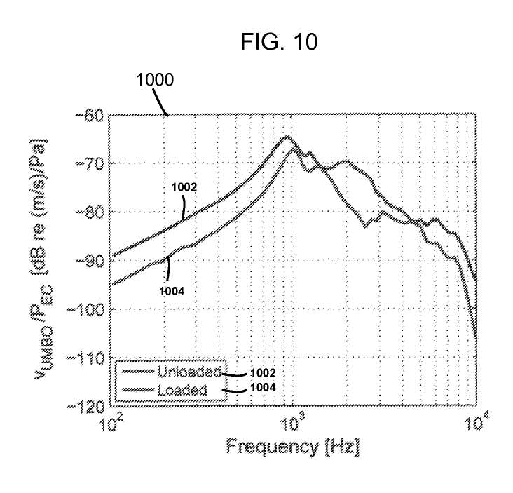

FIG. 10 is a plot 1000 showing the effect of loading an umbo of bone 098 using the piezoelectric sensor illustrated by the transfer characteristic from ear canal pressure (P_{EC}) to umbo velocity (V_{UMBO}) with and without loading. Curve 1002 represents the unloaded case without coupling by the piezoelectric sensor, and curve 1004 represents the loaded case. On average over shown spectrum, loading of the umbo decreased the umbo velocity by about 5 dB or less.

Transfer Characteristics

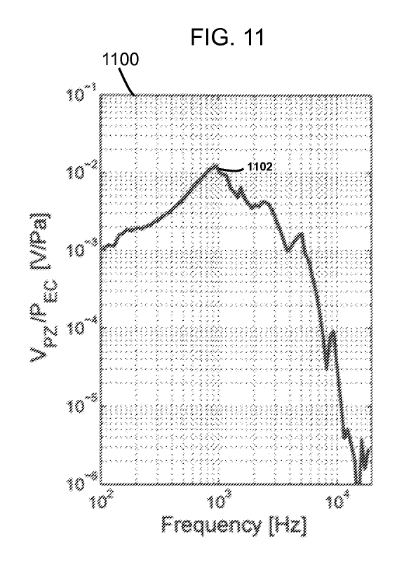

FIG. 11 is a plot 1100 showing measured transfer characteristics from ear canal pressure (P_{EC}) to charge amplifier output (V_{PZ}) as a function of frequency. Curve 1102 is the results measured from bone 096. The results in this measurement show that the V_{PZ}/P_{EC} response had an increasing slope of +6 dB/octave up to around 1 kHz. Most cochlear implant sound processing strategies use a pre-emphasis high-pass filter with a slope of +6 dB/octave up to 1.2 kHz, where the pre-emphasis high-pass filter compensates for the −6 dB/octave roll-off which occurs in speech spectrum originating from the lips. The measured results in plot 1100 show that the VPZ/PEC response of the implemented piezoelectric sensor and charge amplifier circuit can act as a pre-emphasis filter. Therefore, systems including the implemented piezoelectric sensor and charge amplifier circuit can already have the pre-emphasis filtering.

### OTHER EMBODIMENTS

It is to be understood that while the invention has been described in conjunction with the detailed description thereof, the foregoing description is intended to illustrate and not limit the scope of the invention, which is defined by the scope of the appended claims. Other aspects, advantages, and modifications are within the scope of the following claims.

1. An implantable system for providing auditory signals to a subject, the system comprising:
a piezoelectric sensor configured to be implanted in the subject's middle ear to detect mechanical vibrations of the subject's umbo and to generate electric signals corresponding to the detected vibrations; and
a support structure having an elongated shape, wherein a first end of the elongated support structure is configured to be connected to the piezoelectric sensor, and a second end of the support structure positioned away from the first end is configured to be fixed to a mastoid bone or other bony structure in the subject's middle ear.

2. The system of claim 1, wherein:
the piezoelectric sensor has an elongated shape; and
the support structure comprises a ball joint that can be used to adjust an angle between the piezoelectric sensor and the support structure.

3. The system of claim 2, wherein the piezoelectric sensor is shaped as a slab and comprises a cup-like structure to contact the umbo.

4. The system of claim 1, further comprising an anchor structure that is configured to be connected to one end of the piezoelectric sensor, wherein the one end of the piezoelectric sensor is opposite to another end of the piezoelectric sensor that connects to the support structure; and
wherein the anchor structure is configured to be fixed to a bony wall of the middle ear of the subject.

5. The system of claim 4, wherein the anchor structure comprises material selected from the group consisting of titanium, plastic, silicone, and composite materials.

6. The system of claim 1, wherein the piezoelectric sensor comprises a portion shaped to encompass and contact the umbo of the subject.

7. The system of claim 1, wherein the support structure comprises material selected from the group consisting of titanium, plastic, and silicone.

8. The system of claim 1, wherein:
the piezoelectric sensor is shaped as a plate;
the support structure comprises an extension with a first surface and a second surface opposite to the first surface;
the first surface faces towards the plate of the piezoelectric sensor and contacts the plate of the piezoelectric sensor; and
the second surface faces away from the plate of the piezoelectric sensor and towards the cochlear promontory bone in the middle ear of the subject.

9. The system of claim 8, wherein the extension is shaped as a disc.

10. The system of claim 8, further comprising a base element that is configured to contact a bottom surface of the extension;
wherein the piezoelectric sensor, the extension, and the base element are arranged along a direction of motion of an umbo of the subject.

11-12. (canceled)

13. A method for providing auditory signals to a subject, the method comprising:
obtaining a piezoelectric sensor configured to be implanted in the subject's middle ear to detect mechanical vibrations of the subject's umbo and to generate electric signals corresponding to the detected vibrations;
obtaining a support structure having an elongated shape, wherein a first end of the elongated support structure is configured to be connected to the piezoelectric sensor, and wherein a second end of the support structure positioned away from the first end is configured to be fixed to a mastoid bone or other bony structure in the subject's middle ear;
connecting the first end of the support structure to the piezoelectric sensor;
attaching the second end of the support structure to a mastoid bone or other bony structure in the subject's middle ear;
connecting the piezoelectric sensor either directly or indirectly to the subject's umbo;
detecting mechanical vibrations of the subject's umbo; and
providing an auditory signal to the subject based on the detected mechanical vibrations.

14-15. (canceled)

16. The method of claim 13, wherein the first end of the piezoelectric sensor comprises a ball joint; and wherein the method comprises adjusting an angle between the piezoelectric sensor and the support structure using the ball joint.

17. The method of claim 13, further comprising:
connecting an anchor structure to the first end of the piezoelectric sensor; and
attaching the anchor structure to a bony structure in the middle ear of the subject.

18. (canceled)

19. The method of claim 13, wherein the first end of the piezoelectric sensor comprises a portion shaped to encompass and contact the umbo.

20. The method of claim 13, wherein the support structure comprises material selected from the group consisting of titanium, plastic, composite material, and silicone.

21. The method of claim 13, wherein:
the piezoelectric sensor is shaped as a plate;
the support structure comprises an extension with a first surface and a second surface opposite to the first surface;
the first surface faces towards the plate of the piezoelectric sensor and is configured to contact the plate of the piezoelectric sensor; and
the second surface faces away from the plate of the piezoelectric sensor and towards a bony cochlear promontory surface in the middle ear of the subject.

22. The method of claim 21, wherein the extension is shaped as a disc.

23. The method of claim 21, further comprising positioning a base element to contact the bottom of the extension,
wherein the piezoelectric sensor, the extension, and the base element are arranged along a direction of motion of the umbo of the subject.

24. The method of claim 23, wherein the base element comprises compliant medical-grade silicone.

25. The method of claim 23, further comprising fixing the base element to the promontory of the cochlear bone in the middle ear using bone cement or other adhesive.
